(19) United States
(12) Patent Application Publication
(10) Pub. No.: US 2026/0150214 A1
(43) Pub. Date: May 28, 2026

(54) Mounting Ear Apparatus for Server, and Server

(71) Applicant: SUZHOU METABRAIN INTELLIGENT TECHNOLOGY CO., LTD., Suzhou, Jiangsu (CN)

(72) Inventors: Hui TIAN, Suzhou, Jiangsu (CN); Yu ZOU, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 19/121,303

(22) PCT Filed: Mar. 28, 2024
(86) PCT No.: PCT/CN2024/084566

§ 371 Date: Apr. 15, 2025

(30) Foreign Application Priority Data
May 26, 2023 (CN) 202310607940.6

(51) Int. Cl. H05K 7/14; H05K 7/18

(52) U.S. Cl. CPC H05K 7/1417; H05K 7/1491; H05K 7/1492; H05K 7/183

(57) ABSTRACT

A mounting ear apparatus for a server, and a server are provided. The mounting ear apparatus includes: a mounting mechanism, the mounting mechanism is connected to a chassis and/or a rack; a mounting ear, the mounting ear is actively connected to the mounting mechanism, and has a working state of being mounted on the mounting mechanism and a disassembled state of being separated from the mounting mechanism, and the mounting ear is internally provided with a control board configured to be electrically connected to a device in the chassis; and a locking mechanism, the locking mechanism is arranged between the mounting ear and the mounting mechanism, and is able to lock the mounting ear in the working state, the locking mechanism is provided with an operating end for unlocking, and the operating end is located at a front surface or a side surface of the mounting ear.

### CROSS-REFERENCE TO RELATED APPLICATIONS

The present disclosure is a National Stage Filing of the PCT International Application No. PCT/CN2024/084566 filed on Mar. 28 2024, which claims the priority and the benefit of Chinese Patent Application No. 202310607940.6, filed with the China National Intellectual Property Administration (CNIPA) on May 26, 2023 and entitled “Mounting Ear Apparatus for Server, and Server”, which is herein incorporated by reference in its entirety.

### TECHNICAL FIELD

The present disclosure relates to the technical field of computers, and in particularly to a mounting ear apparatus for a server, and a server.

### BACKGROUND

At present, a chassis of a rack-mounted server is generally equipped with an intelligent mounting ear for startup, shutdown, state indication, etc. All these functions are achieved through a process control block (PCB) mounted in the mounting ear. The PCB is connected to a mainboard in the chassis through a cable, so as to implement power supply and signal connection.

A currently common fixing method of a mounting ear of the rack-mounted server is to use screws to lock a back surface of the mounting ear. After the server is mounted on a rack, if the PCB in the mounting ear fails, the internal PCB can be replaced only after the entire server is removed from the rack and the screws are removed from the back surface of the mounting ear. Specific maintenance steps are as follows: 1, the entire chassis is pulled out of the rack; 2, fixing screws of a plastic housing on the back surface of the mounting ear are removed; 3, PCB fixing screws are removed; and 4, a signal cable is removed. This maintenance process is extremely complicated, in which the server needs to be removed from the rack, causing service interruption.

### SUMMARY

The present disclosure provides a mounting ear apparatus for a server, and a server, so as to at least solve a problem that a mounting ear of a server is inconvenient to maintain in the related art.

Some embodiments of the present disclosure provide a mounting ear apparatus for a server. The mounting ear apparatus includes: a mounting mechanism, the mounting mechanism is connected to a chassis and/or a rack; a mounting ear, the mounting ear is actively connected to the mounting mechanism, and has a working state of being mounted on the mounting mechanism and a disassembled state of being separated from the mounting mechanism, and the mounting ear is internally provided with a control board configured to be electrically connected to a device in the chassis; and a locking mechanism, the locking mechanism is arranged between the mounting ear and the mounting mechanism, and is able to lock the mounting ear in the working state, the locking mechanism is provided with an operating end for unlocking, and the operating end is located at a front surface or a side surface of the mounting ear.

In some embodiments, the mounting ear is movably connected to the mounting mechanism, and a moving direction of the mounting ear relative to the mounting mechanism is non-parallel to a direction in which the chassis extends out of the rack.

In some embodiments, the mounting ear apparatus further includes a limiting mechanism, the limiting mechanism includes a first limiting portion arranged on the mounting ear and a second limiting portion arranged on the mounting mechanism, the first limiting portion and the second limiting portion all extend in a moving direction of the mounting ear, and when the mounting ear is mounted on the mounting mechanism, the first limiting portion abuts against the second limiting portion.

In some embodiments, at least one of the first limiting portion and the second limiting portion is provided with a sliding slot, and when the first limiting portion and the second limiting portion match each other in a butted manner, a portion of the first limiting portion is located in the sliding slot of the second limiting portion and/or a portion of the second limiting portion is located in the sliding slot of the first limiting portion.

In some embodiments, there are a plurality of first limiting portions and a plurality of second limiting portions, and the plurality of first limiting portions are arranged in one-to-one correspondence to the plurality of second limiting portions, and two opposite sides of the mounting ear are both provided with the first limiting portion.

In some embodiments, the first limiting portion and the second limiting portion are provided with a guide rail structure.

In some embodiments, the limiting mechanism further includes a third limiting portion arranged on the mounting ear and a fourth limiting portion arranged on the mounting mechanism, the third limiting portion and the fourth limiting portion extend in a direction perpendicular to the moving direction of the mounting ear, and when the mounting ear is mounted on the mounting mechanism in place, the third limiting portion abuts against the fourth limiting portion.

In some embodiments, one of the third limiting portion and the fourth limiting portion is a protrusion, and the other one of the third limiting portion and the fourth limiting portion is a recess, an extension direction of the protrusion and an opening direction of the recess both extend in the moving direction of the mounting ear, and when the mounting ear is mounted on the mounting mechanism in place, the protrusion is located in the recess.

In some embodiments, the mounting ear includes a housing, a side of the housing is an opening side, the opening side is mounted on the mounting mechanism in a butted manner, and the limiting mechanism is arranged at an edge of the opening side.

In some embodiments, the edge of the opening side is provided with a notch allowing a cable to extend out.

In some embodiments, the locking mechanism includes: a locking member, the locking member is actively connected to the mounting ear; and a locking hole, the locking hole is located on the mounting mechanism, and when the mounting ear is in the working state, the locking member is located in the locking hole and prevents the mounting ear from moving to the disassembled state.

In some embodiments, the locking member is movably arranged relative to the mounting ear, and a moving direction of the locking member is non-parallel to a moving direction of the mounting ear mounted on the mounting mechanism.

In some embodiments, the locking member includes: a locking portion, the locking portion is located in the mounting ear, and the locking portion is provided with a locking end configured to match the locking hole; and an operating portion, the operating portion is located at an outer side of the mounting ear, the operating portion and the locking portion are connected to each other and move synchronously, and the operating portion is provided with the operating end.

In some embodiments, the locking mechanism further includes a locking reset member, the locking reset member abuts against the locking member, and provides a reset force for the locking member to move in a direction extending into the locking hole.

In some embodiments, the mounting mechanism includes a mounting portion and a housing portion, the mounting portion is connected to the housing portion, the locking mechanism is located at the mounting portion, and the housing portion is provided with an accommodating cavity configured to accommodate a component.

In some embodiments, the mounting ear apparatus further includes a stretchable mechanism, the stretchable mechanism is arranged in the chassis, a cable is wound around the stretchable mechanism, at least a portion of the stretchable mechanism is actively arranged, when the mounting ear is in the disassembled state, the cable connected to the mounting ear drives the stretchable mechanism to move, such that a length of the cable extending out of the chassis is increased, and when the mounting ear is in the working state, the stretchable mechanism drives the cable to retract into the chassis.

In some embodiments, the stretchable mechanism includes: a support, the support is arranged in the chassis; and a sliding member, the sliding member is movably arranged on the support, and the cable winds through the sliding member, and when the mounting ear is disassembled, the mounting ear pulls the cable, and the cable drives the sliding member to move, such that the length of the cable extending out of the chassis is changed.

In some embodiments, a moving direction of the sliding member is parallel to an extension direction of the cable.

In some embodiments, the sliding member is provided with a winding column, and the cable winds through the winding column, and drives the winding column to pull the sliding member to move.

In some embodiments, the stretchable mechanism further includes a stretchable reset member, and the stretchable reset member is connected to the sliding member and drives the sliding member to move in a direction of pulling the cable to retract into the chassis.

In some embodiments, the support has a sliding region, the sliding region extends in a moving direction of the sliding member, and the sliding member is accommodated in the sliding region.

Some other embodiments of the present disclosure provide a server, the server includes a chassis and the above mounting ear apparatus for a server, the mounting ear apparatus is mounted on the chassis.

In the present disclosure, the mounting ear is actively arranged on the mounting mechanism, such that the mounting ear is able to be conveniently removed from the mounting mechanism, meanwhile, the locking mechanism plays a role in locking the mounting ear to the mounting mechanism. Specifically, during mounting, the mounting ear is connected to the mounting mechanism in a butted manner, such that the mounting ear is moved to a specific position on the mounting mechanism, when the mounting ear moves to the working state, the locking mechanism automatically locks the mounting ear to the mounting mechanism, such that the mounting ear is able to be mounted on the chassis or the rack through the mounting mechanism, when the mounting ear needs to be repaired, an operator directly operates the operating end from the front surface or the side surface, such that the locking mechanism unlocks the mounting ear from the mounting mechanism, thus, the mounting ear is able to be moved again, then the mounting ear is able to be removed from the mounting mechanism through reverse movement, and then the control board and other components in the mounting ear is able to be overhauled. Through the above arrangement, the mounting ear and the control board are able to be removed from a front face plate of the mounting ear in a case that the server is not removed from the rack, thus, the mounting ear, the control board and other components are conveniently replaced, such that a problem of service interruption due to a fact that a traditional rack server is inconvenient to maintain and a mounting ear has to be removed from the rack for maintenance is solved.

### BRIEF DESCRIPTION OF THE DRAWINGS

FIG. 1 is a schematic structural diagram of a mounting ear apparatus mounted on a chassis of an embodiment according to the present disclosure;

FIG. 2 is a schematic structural diagram of a mounting ear of a mounting ear apparatus removed from a mounting mechanism according to an embodiment of the present disclosure;

FIG. 3 is a schematic structural diagram of a mounting ear of a mounting ear apparatus replaced and maintained on a mounting mechanism according to an embodiment of the present disclosure;

FIG. 4 is a schematic structural diagram of a mounting ear matching with a mounting mechanism according to an embodiment of the present disclosure;

FIG. 5 is an exploded view of a mounting ear according to an embodiment according to the present disclosure;

FIG. 6 is a schematic structural diagram of a locking portion and a locking reset member according to an embodiment of the present disclosure; and

FIG. 7 is an exploded view of a stretchable mechanism according to an embodiment of the present disclosure.

The figures include the following reference numerals:
10, mounting mechanism; 11, mounting portion; 12, housing portion; 20, mounting ear; 21, control board; 22, housing; 31, locking member; 311, locking portion; 312, operating portion; 32, locking hole; 33, locking reset member; 40, limiting mechanism; 41, first limiting portion; 42, second limiting portion; 421, sliding slot; 43, third limiting portion; 44, fourth limiting portion; 50, stretchable mechanism; 51, support; 52, sliding member; and 53, stretchable reset member.

### DETAILED DESCRIPTION OF THE EMBODIMENTS

Embodiments of the present disclosure will be described in detail below with reference to the accompanying drawings in conjunction with the embodiments.

It should be noted that the embodiments in the present disclosure and features in the embodiments can be combined with one another if there is no conflict. The present disclosure will be described in detail below with reference to the accompanying drawings in conjunction with the embodiments.

It should be noted that all technical and scientific terms used in the present disclosure have same meanings as commonly understood by those of ordinary skill in the art to which the present disclosure belongs unless otherwise indicated.

In the present disclosure, unless otherwise stated, the orientation words such as “upper”, “lower”, “top” and “bottom” are generally used for directions shown in the drawings, or for components that are in a vertical direction, a perpendicular direction or a gravity direction; and similarly, for convenience of understanding and description, “inside” or “outside” refers to inside or outside relative to an outline of each component itself, but the above orientation words are not used to limit the present disclosure.

In order to solve a problem that a mounting ear of a server is inconvenient to maintain in the related art, the present disclosure provides a mounting ear apparatus for a server, and a server. The server is provided with the following mounting ear apparatus.

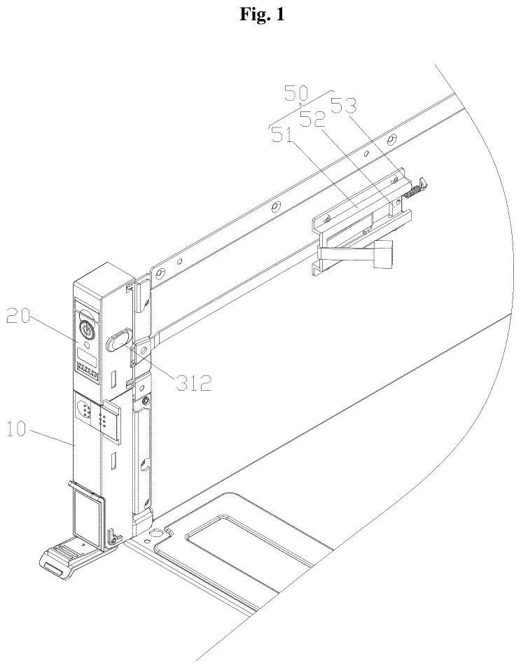

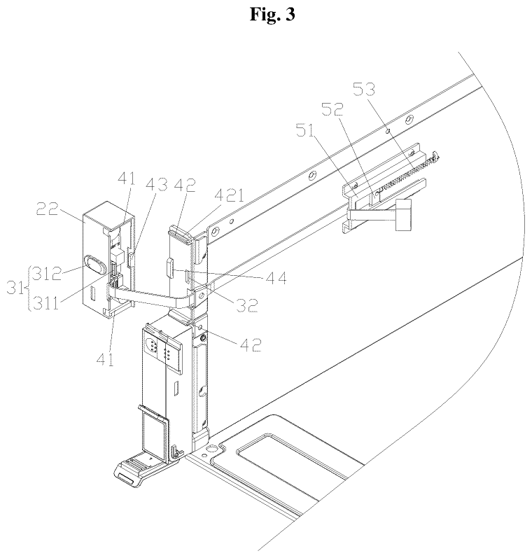

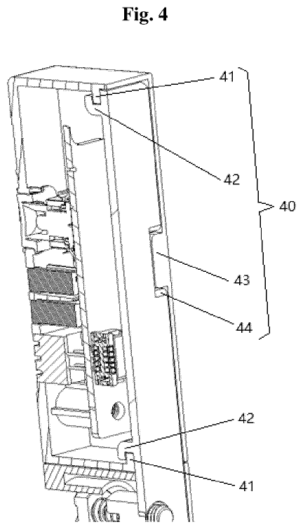

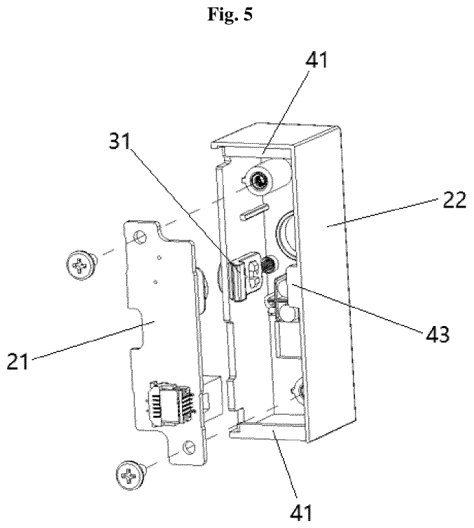

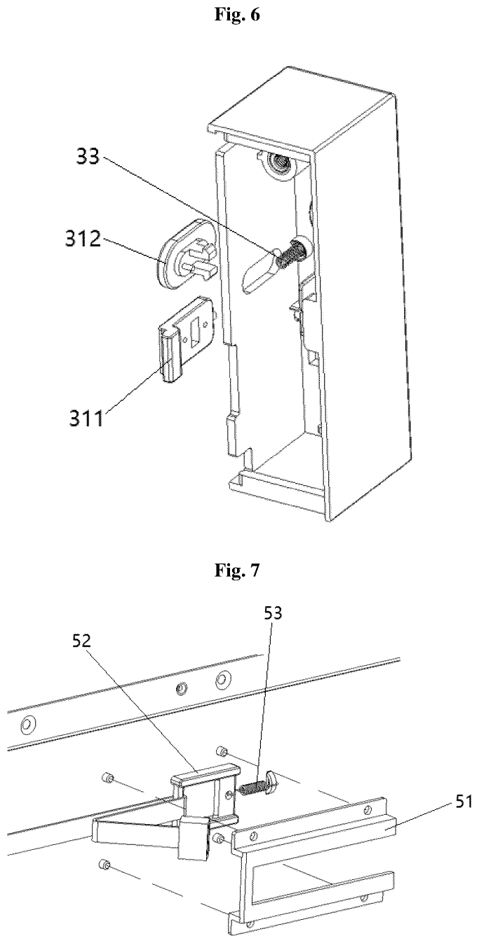

As shown in FIGS. 1-7, the embodiment provides a mounting ear apparatus for a server, the mounting ear apparatus includes: a mounting mechanism 10, a mounting ear 20, and a locking mechanism, the mounting mechanism 10 is connected to a chassis and/or a rack; the mounting ear 20 is actively connected to the mounting mechanism 10, and has a working state of being mounted on the mounting mechanism 10 and a disassembled state of being separated from the mounting mechanism 10; the mounting ear 20 is internally provided with a control board 21 configured to be electrically connected to a device in the chassis; the locking mechanism is arranged between the mounting ear 20 and the mounting mechanism 10, and is able to lock the mounting ear 20 in the working state, the locking mechanism is provided with an operating end for unlocking, and the operating end is located at a front surface or a side surface of the mounting ear 20.

In the embodiment, the mounting ear 20 is actively arranged on the mounting mechanism 10, such that the mounting ear 20 is able to be conveniently removed from the mounting mechanism 10, meanwhile, the locking mechanism plays a role in locking the mounting ear 20 to the mounting mechanism 10. Specifically, during mounting, the mounting ear 20 is connected to the mounting mechanism 10 in a butted manner, such that the mounting ear 20 is moved to a specific position on the mounting mechanism 10, when the mounting ear 20 moves to the working state, the locking mechanism automatically locks the mounting ear 20 to the mounting mechanism 10, such that the mounting ear 20 is able to be mounted on the chassis or the rack through the mounting mechanism 10, when the mounting ear 20 needs to be repaired, an operator directly operates the operating end from the front surface or the side surface, such that the locking mechanism unlocks the mounting ear 20 from the mounting mechanism 10, thus, the mounting ear 20 is able to be moved again, then the mounting ear 20 is able to be removed from the mounting mechanism 10 through reverse movement, and then the control board 21 and other components in the mounting ear 20 is able to be overhauled. Through the above arrangement, the mounting ear 20 and the control board 21 are able to be removed from a front face plate of the mounting ear 20 in a case that the server is not removed from the rack, thus, the mounting ear 20, the control board 21 and other components are conveniently replaced, such that a problem of service interruption due to a fact that a traditional rack server is inconvenient to maintain and a mounting ear 20 has to be removed from the rack for maintenance are solved.

It should be noted that directions of a front surface, a side surface and a back surface mentioned in the embodiment are defined as follows: when an operator directly faces the chassis under a normal condition, one side directly faced by the operator is the front surface, left and right sides are the side surfaces, and a rear side is the back surface.

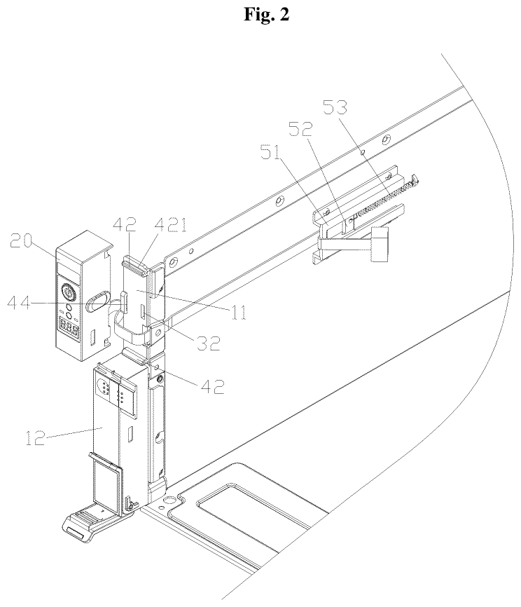

In the embodiment, the mounting ear 20 is movably connected to the mounting mechanism 10, and a moving direction of the mounting ear 20 relative to the mounting mechanism 10 is perpendicular to a direction in which the chassis extends out of the rack. In this way, when the mounting ear 20 is mounted, it is convenient and quick to slide the mounting ear 20 onto the mounting mechanism 10 from the left and right sides, as shown in FIGS. 1-2. In addition to a movable mounting manner, a rotatable mounting manner may be used. That is, the mounting ear 20 may be rotatably mounted on the mounting mechanism 10. Moreover, even if the movable mounting manner of the embodiment is used, the moving direction of the mounting ear 20 is not limited to a direction perpendicular to a moving direction of the chassis, and may be an oblique direction, as long as the moving direction of the mounting ear is non-parallel to the moving direction of the chassis in most cases.

As shown in FIGS. 2-4, in the embodiment, the mounting ear apparatus further includes a limiting mechanism 40. The limiting mechanism 40 includes a first limiting portion 41 arranged on the mounting ear 20 and a second limiting portion 42 arranged on the mounting mechanism 10. The first limiting portion 41 and the second limiting portion 42 all extend in a moving direction of the mounting ear 20. The first limiting portion 41 and the second limiting portion 42 limit movement of the mounting ear 20. When the mounting ear 20 is movably mounted on the mounting mechanism 10, the first limiting portion 41 abuts against the second limiting portion 42. Due to stopping and limiting between the first limiting portion 41 and the second limiting portion 42, the mounting ear 20 may only move in an expected direction, such that stable and reliable mounting of the mounting ear 20 is ensured. Meanwhile, after mounting is completed, the first limiting portion 41 and the second limiting portion 42 may still keep stopping and limiting, such that movement of the mounting ear 20 may still be limited after mounting, and the mounting ear 20 may be locked through cooperation of the locking mechanism.

It should be noted herein that the reason why the limiting mechanism 40 is arranged in the embodiment is that a specific solution of the locking mechanism of the embodiment is not able to limit movement of the mounting ear 20 in all directions after the mounting ear is mounted, so the limiting mechanism 40 is arranged. The limiting mechanism 40 is able to assist in limiting the mounting ear in a direction in which the locking mechanism is not able to limit the mounting ear, such that the limiting mechanism 40 may not only play a limiting and guiding role during mounting, but also play a role of assisting in limiting after mounting is completed. In actual use, only the locking mechanism may be provided, and the locking mechanism may be of another structure that may play a limiting role better, such as a buckle structure and a hook structure.

In the embodiment, both the first limiting portion 41 and the second limiting portion 42 are provided with a guide rail structure. A length direction, that is, an extension direction, of the guide rail structure is a left-right direction, so as to play a guiding role in a mounting process.

In addition, at least one of the first limiting portion 41 and the second limiting portion 42 is provided with a sliding slot 421. When the first limiting portion 41 and the second limiting portion 42 match each other in a butted manner, a portion of the first limiting portion 41 is located in the sliding slot 421 of the second limiting portion 42 or a portion of the second limiting portion 42 is located in the sliding slot 421 of the first limiting portion 41, or a portion of the first limiting portion 41 is located in the sliding slot 421 of the second limiting portion 42 and a portion of the second limiting portion 42 is located in the sliding slot 421 of the first limiting portion 41. The second limiting portion 42 of the embodiment is of an L-shaped structure, and an end of the second limiting portion is connected to the mounting mechanism 10, such that the sliding slot 421 is enclosed by the L-shaped structure and a surface of the mounting mechanism 10. A long opening direction of the sliding slot 421 is upward or downward, and the first limiting portion 41 is normal strip-shaped. When the first limiting portion 41 and the second limiting portion 42 match each other in a butted manner, a portion of the first limiting portion 41 extends into the sliding slot 421, and then the first mounting portion 11 moves along the sliding slot 421 while the mounting ear 20 is mounted, such that the mounting ear 20 is mounted. After mounting is completed, due to stopping and matching between the sliding slot 421 and the first limiting portion 41, the mounting ear 20 is limited in a front direction. The mounting ear is limited in a rear direction naturally due to the mounting mechanism 10, and no additional arrangement is required.

In an embodiment, there are a plurality of first limiting portions 41 and a plurality of second limiting portions 42, and the plurality of first limiting portions 41 are arranged in one-to-one correspondence to the plurality of second limiting portions 42. Two opposite sides of the mounting ear 20 are both provided with the first limiting portion 41. In the embodiment, two first limiting portions 41 and two second limiting portions 42 are provided, and the two first limiting portions and the two second limiting portions are paired one by one. The first limiting portion 41 and the second limiting portion 42 that are paired match with each other in the described above structural manner. The mounting ear 20 of the embodiment is mounted in a left-right moving manner, such that the two first limiting portions 41 are arranged at an upper side and a lower side of the mounting ear 20. Accordingly, the two second limiting portions 42 are also arranged at an upper side and a lower side of the mounting mechanism 10. A difference between the two second limiting portions 42 is that opening directions of the sliding slots 421 formed are opposite. In the embodiment, an opening of an upper sliding slot 421 is upward, and an opening of a lower sliding slot 421 is downward. Of course, openings of the sliding slots may be arranged in opposite directions. In this way, the two first limiting portions 41 and the two second limiting portions 42 at the upper and lower sides may ensure that the mounting ear 20 is limited both in upper and lower directions. Through cooperation of the manner of limitation in front and rear directions, the mounting ear 20 is limited by the limiting mechanism 40 in the upper and lower directions and the front and rear directions. In the embodiment, limiting and locking in the left-right direction are implemented by the locking mechanism, and the specific solution of the locking mechanism will be described in detail below.

In addition that only the second limiting portion 42 is provided with the sliding slot 421, the first limiting portion 41 may also be provided with the sliding slot 421. That is, a structure of the first limiting portion 41 and that of the second limiting portion 42 is exchanged. Alternatively, both the first limiting portion 41 and the second limiting portion 42 may be provided with the sliding slot 421, and may match each other through symmetrical fastening.

In an embodiment, in addition to the plurality of first limiting portions 41 and the plurality of second limiting portions 42, only one first limiting portion 41 and only one second limiting portion 42 may also be arranged. The sliding slot 421 of the second limiting portion 42 is closed in upper and lower directions and opened at a front surface and a side portion. In this way, when the first limiting portion 41 is located inside the second limiting portion 42, limitation may be achieved in both the upper and lower moving directions by the sliding slot 421, and limitation may be achieved in front and rear moving directions by the mounting mechanism 10 and a front portion of the sliding slot 421. Thus, movement of the mounting ear 20 is limited by the limiting mechanism 40 in directions other than the left and right directions.

In the embodiment, in addition to the first limiting portion 41 and the second limiting portion 42, the limiting mechanism 40 further includes a third limiting portion 43 arranged on the mounting ear 20 and a fourth limiting portion 44 arranged on the mounting mechanism 10. The third limiting portion 43 and the fourth limiting portion 44 extend in a direction perpendicular to the moving direction of the mounting ear 20. When the mounting ear 20 is mounted on the mounting mechanism 10 in place, the third limiting portion 43 abuts against the fourth limiting portion 44.

Different from structures of the first limiting portions 41 and the second limiting portions 42, the third limiting portion 43 and the fourth limiting portion 44 of the embodiment are located at one of left and right sides of the mounting ear 20. The third limiting portion and the fourth limiting portion are only arranged at one side by considering that the mounting ear 20 needs to move and be connected to the mounting mechanism 10 in a butted manner, such that one side is required for avoidance to facilitate mounting. Based on the direction in FIG. 1, the third limiting portion 43 and the fourth limiting portion 44 are located at a left side of the mounting ear 20. In a moving process of the mounting ear 20, no matching relation is set between the third limiting portion 43 and the fourth limiting portion 44. When the mounting ear 20 is mounted in place, the third limiting portion 43 and the fourth limiting portion 44 may match each other in a butted manner to play a limiting role, such that the mounting ear 20 is prevented from being mounted out of place.

In an embodiment, the third limiting portion 43 and the fourth limiting portion 44 may not be arranged. In this case, in order to avoid out-of-place movement, left or right ends of the first limiting portion 41 and the second limiting portion 42 may be provided with plugs, such that an effect of preventing continuous movement after the mounting ear moves in place may be achieved through cooperation of the plugs.

In an embodiment, one of the third limiting portion 43 and the fourth limiting portion 44 is a protrusion, and the other one of the third limiting portion 43 and the fourth limiting portion 44 is a recess. An extension direction of the protrusion and an opening direction of the recess both extend in the moving direction of the mounting ear 20. When the mounting ear 20 is mounted on the mounting mechanism 10 in place, the protrusion is located in the recess. In the embodiment, the third limiting portion 43 is the protrusion, and the protrusion extends in the left-right direction. The fourth limiting portion 44 is the recess, and a front direction of the recess is not open while left and right sides of the recess are open. In this way, when the mounting ear 20 is mounted in place, the protrusion may extend into the recess from openings at the left and right sides, and the protrusion abuts against the recess, such that continuous movement is stopped. Meanwhile, a front surface of the recess is not open, and the recess further prevents the protrusion from moving forward, such that the mounting ear 20 is further prevented from moving forward, achieving a multi-directional limiting effect. In another embodiment, structural forms of the protrusion and the recess may be exchanged or may be other structural forms.

In the embodiment, the mounting ear 20 includes a housing 22. A side of the housing 22 is an opening side. A control board 21, an interface and other components in the mounting ear 20 are all mounted in the housing 22 through the opening side. Meanwhile, when the mounting ear 20 is mounted, the opening side is mounted on the mounting mechanism 10 in a butted manner, and the mounting mechanism 10 shields the opening side, such that the housing 22 is closed. In this way, on one hand, a form of the housing 22 may facilitate mounting, dismounting and replacement of components in the mounting ear 20 and maintenance. On the other hand, the housing may conveniently match the mounting mechanism 10. Meanwhile, the first limiting portion 41 and the third limiting portion 43 of the limiting mechanism 40 are arranged at an edge of the opening side, such that cooperation of all parts of the limiting mechanism 40 may be ensured.

In the embodiment, the edge of the opening side is provided with a notch, and the notch is configured to allow the cable to extend out, such that smooth wiring of the cable is ensured. The housing 22 may also be provided with a display screen, a key, a switch, an indicator light, and other components.

As shown in FIGS. 2, 3, 5 and 6, in the embodiment, the locking mechanism includes a locking member 31 and a locking hole 32. The locking member 31 is actively connected to the mounting ear 20. The locking hole 32 is located on the mounting mechanism 10. In addition, when the mounting ear 20 is in the working state, the locking member 31 is located in the locking hole 32 and prevents the mounting ear 20 from moving to the disassembled state. The locking mechanism of the embodiment is configured to hinder lateral movement of the mounting ear 20, and does not hinder movement of the mounting ear 20 in other directions. Thus, the limiting mechanism 40 is arranged for matching.

In the embodiment, the locking member 31 is movably arranged relative to the mounting ear 20. In addition, a moving direction of the locking member 31 is non-parallel to a moving direction of the mounting ear 20 mounted on the mounting mechanism 10. In the embodiment, the moving direction of the locking member is perpendicular to the moving direction of the mounting ear mounted on the mounting mechanism, that is, the locking member 31 moves in a front-rear direction. Accordingly, the locking hole 32 is provided in the front-rear direction. Thus, when the mounting ear 20 is mounted in place, the locking member 31 is aligned with the locking hole 32, and the locking member 31 may move and extend into the locking hole 32, such that the mounting ear 20 is not able to further move, and the mounting ear 20 is locked. When the mounting ear 20 needs to be disassembled, an operator may move the locking member 31 to enable the locking member 31 to retreat from the locking hole 32, such that the mounting ear 20 may be unlocked, and the mounting ear 20 may be moved for dismounting.

In the embodiment, the locking member 31 includes a locking portion 311 and an operating portion 312. The locking portion 311 is located in the mounting ear 20. The locking portion 311 is provided with a locking end configured to match the locking hole 32. The operating portion 312 is located at an outer side of the mounting ear 20. The operating portion 312 and the locking portion 311 are connected to each other and move synchronously. The operating portion 312 is provided with the operating end. That is, the locking portion 311 is a part that matches the locking hole 32, and the operating portion 312 is a part that may be operated by the personnel. The locking portion and the operating portion may be connected together through a structure such as a buckle, and a joint between the locking portion and the operating portion penetrates a long hole in the housing 22, such that the locking member 31 may move on the housing 22. Of course, a specific structure of the locking member 31 may be changed as required, and is not limited to the manner described in the embodiment.

In the embodiment, the locking mechanism further includes a locking reset member 33. Components such as a spring may be used as the locking reset member 33. The locking reset member 33 abuts against the locking member 31, and provides a reset force for the locking member 31 to move in a direction extending into the locking hole 32. In this way, when the locking member 31 is not operated, the locking member 31 always tends to extend into the locking hole 32. After the mounting ear 20 is mounted in place, the locking member 31 may automatically extend into the locking hole 32 under the action of the locking reset member 33. Thus, automatic locking is implemented, and meanwhile, stability and reliability after locking are ensured.

In the embodiment, the mounting mechanism 10 includes a mounting portion 11 and a housing portion 12. The mounting portion 11 is connected to the housing portion 12. The mounting portion 11 is a plate-shaped member, and a front surface of the mounting portion is provided with a second limiting portion 42 and a fourth limiting portion 44. That is, the locking mechanism is located at the mounting portion 11. Thus, the mounting portion 11 may match with the mounting ear 20 and other parts of the limiting mechanism 40 on the mounting ear 20. The housing portion 12 is provided with an accommodating cavity configured to accommodate a component, such that the housing portion 12 may be connected to the chassis and the rack, and meanwhile, other devices may be arranged in the accommodating cavity as required.

In the embodiment, in consideration of the fact that a portion of the cable connected to the mounting ear 20 may be pulled out when the mounting ear 20 is disassembled and overhauled, the mounting ear apparatus of the embodiment is further provided with a stretchable mechanism 50 configured for extension of the cable. The stretchable mechanism 50 is arranged in the chassis, the cable is wound around the stretchable mechanism 50, and at least a portion of the stretchable mechanism 50 is actively arranged. When the mounting ear 20 is disassembled and the mounting ear 20 is in the disassembled state, if the mounting ear 20 is removed, a portion of the cable is inevitably pulled out. In this case, the cable connected to the mounting ear 20 is pulled out to drive the stretchable mechanism 50 to move, such that a length of the cable extending out of the chassis is increased, and dismounting and maintenance of the mounting ear 20 are facilitated. After the mounting ear 20 is overhauled and remounted on the mounting mechanism 10 and the mounting ear 20 is in the working state, the stretchable mechanism 50 drives the cable to retract into the chassis, such that the cable may always be tensioned, functions of stretching and automatically retracting the cable may be achieved, and redundant accumulation of the cable may be avoided.

As shown in FIGS. 1-3 and 7, in the embodiment, the stretchable mechanism 50 includes a support 51 and a sliding member 52. The support 51 is arranged in the chassis, and is a fixed part. The sliding member 52 is movably arranged on the support 51, and is a movable part. The cable winds through the sliding member 52. In this way, when the mounting ear 20 is disassembled, the mounting ear 20 pulls the cable, and the cable drives the sliding member 52 to move in a direction in which the cable extends out, such that a portion of the cable may extend out of the chassis under the action of ensuring tension of the cable through movement of the sliding member 52. Thus, the length of the cable extending out of the chassis is increased, and maintenance of the mounting ear 20 is implemented.

In an embodiment, the support 51 is mounted on inner side surfaces of left and right sides of the chassis, and a moving direction of the sliding member 52 is parallel to an extension direction of the cable. Thus, stress of the cable may be reduced, and the cable may be prevented from being stuck or even broken under the action of stress.

The support 51 of the embodiment is of a frame structure. A middle portion of the support is provided with a sliding region, and the sliding region extends in the moving direction of the sliding member 52, that is, a moving direction of the chassis. The sliding member 52 is accommodated in the sliding region, so as to be movable in the sliding region. The sliding member 52 of the embodiment is of a lateral I-shaped structure. That is, the sliding member includes two transverse beams arranged at upper and lower sides and a longitudinal beam. The longitudinal beam is used as a winding column, and the cable winds through the winding column. Generally, the cable only needs to be wound for half a turn. The upper and lower transverse beams match upper and lower sides of the sliding region in a butted manner. In this way, when the cable needs to extend out of the chassis, a pulling force of the cable pulls the winding column. The sliding member 52 is pulled by the winding column to move in the sliding region, such that the length of the cable extending out of the chassis may be increased.

In the embodiment, the stretchable mechanism 50 further includes a stretchable reset member 53. The stretchable reset member 53 may be a spring. One end of the stretchable reset member 53 is connected to the chassis, and the other end of the stretchable reset member is connected to the sliding member 52 and drives the sliding member 52 to move in a direction of pulling the cable to retract into the chassis. In this way, the sliding member 52 always has a force to pull the cable to retract into the chassis. Thus, when the mounting ear 20 is mounted back to the mounting mechanism 10, the stretchable reset member 53 drives the sliding member 52 to automatically move back, so as to drive the cable to automatically retract.

A specific structural form of the stretchable mechanism 50 and a specific structure of each component are not limited to the manner of the embodiment, and may be changed as required, as long as linkage with the cable is implemented and extension and automatic retraction of the cable are implemented.

The present disclosure further provides a server. The server includes a chassis and the mounting ear apparatus. The mounting ear apparatus is mounted on the chassis. The mounting mechanism 10 of the mounting ear apparatus may be mounted on the chassis, the rack, or both the chassis and the rack, so as to fix the chassis.

An entire working process of the mounting ear apparatus of the present disclosure is as follows:
In a normal state, a mounting ear 20 is mounted on a mounting mechanism 10, and a locking member 31 extends into a locking hole 32. Meanwhile, a first limiting portion 41 and a second limiting portion 42 are in limited fit, and a third limiting portion 43 and a fourth limiting portion 44 are in limited fit, such that the mounting ear 20 is fixed to the mounting mechanism 10.

When a component needs to be overhauled or replaced, an operator pushes an operating portion 312 of the locking member 31, such that the entire locking member 31 moves towards the personnel. In this case, the locking member 31 retreats from the locking hole 32, and the mounting ear 20 is unlocked and may move freely. In this case, the operator moves the mounting ear 20 laterally, matching between the third limiting portion 43 and the fourth limiting portion 44 is released, and the mounting ear 20 moves laterally under guidance of two groups of first limiting portions 41 and second limiting portions 42, so as to be removed from the mounting mechanism 10. In the process, the mounting ear 20 moves to pull a cable, and the cable pulls a sliding member 52, such that the sliding member 52 moves towards the personnel accordingly. Thus, a portion of the cable extends out of a chassis. Then, the operator turns the mounting ear 20 in a front-rear direction, such that a rear opening side faces forward. Thus, a component in the mounting ear 20 may be replaced.

When the mounting ear 20 needs to be remounted, the operator places the mounting ear 20 at one side of the mounting mechanism 10, and then moves the mounting ear 20 reversely, such that the first limiting portion 41 and the second limiting portion 42 match each other in a butted manner. Then, the mounting ear 20 is gradually moved in place in a direction guided by the first limiting portion 41 and the second limiting portion 42, and the third limiting portion 43 and the fourth limiting portion 44 are in limited fit again when the mounting ear is in place. In the process, a stretchable reset member 53 drives the sliding member 52 to move away from the personnel, and meanwhile, the cable is driven to gradually retract into the chassis, such that automatic retraction of the cable is implemented.

In the process, the mounting ear 20 is of a detachable structural form, such that when the mounting ear apparatus fails, the operation and maintenance personnel may remove the mounting ear 20 and a control board 21 from a front face plate without shutting the entire apparatus down and removing the entire apparatus from the rack, thus avoiding service interruption. Meanwhile, a mounting method is simple and easy to implement, and may be operated without tools. In addition, a stretchable mechanism 50 achieves functions of stretching and automatically retracting the cable connected to the mounting ear 20 when the mounting ear is disassembled.

It should be noted that plurality in the embodiments indicates at least two.

From the above description, it may be seen that the embodiments of the present disclosure achieve the following technical effects:
1, a problem that a mounting ear of a server is inconvenient to maintain in the related art is solved.
2, the mounting ear and the control board are able to be removed from a front face plate of the mounting ear in a case that the server is not removed from the rack. Thus, the mounting ear, the control board and other components are conveniently replaced, such that a problem of service interruption due to a fact that a traditional rack server is inconvenient to maintain and a mounting ear has to be removed from the rack for maintenance are solved.
3, an overall structure is simple, no tools are used, and the structure is convenient to use, stable and reliable.
4, the stretchable mechanism is able to tension the cable all the time, achieve functions of stretching and automatic retraction of the cable, and avoid redundancy of the cable.

Obviously, the embodiments described above are merely some embodiments rather than all embodiments of the present disclosure. Based on the embodiments of the present disclosure, all other embodiments obtained by those of ordinary skill in the art without making creative efforts should fall within the protection scope of the present disclosure.

It should be noted that the terms used herein are merely for describing the detailed description of embodiments and are not intended to limit illustrative embodiments according to the present disclosure. As used herein, the singular is also intended to include the plural unless the context clearly points out the singular or plural. In addition, it should be understood that terms “include” and/or “comprise” used in the description indicate the presence of features, steps, operations, devices, assemblies, and/or their combinations.

It should be noted that the terms such as “first” and “second” in the description and claims of the present disclosure and in the drawings are configured to distinguish between similar objects and not necessarily to describe a particular order or sequential order. It should be understood that data used in this way can be interchanged where appropriate, such that the embodiments of the present disclosure described herein can be implemented in other orders than those illustrated or described herein.

What are described above are merely preferred embodiments of the present disclosure and are not intended to limit the present disclosure, and various changes and modifications can be made by those skilled in the art. Any modifications, equivalent substitutions, improvements, and the like within the principles of the application are intended to be included within the scope of the present disclosure.

1. A mounting ear apparatus for a server, comprising:
a mounting mechanism wherein the mounting mechanism is configured to be connected to a chassis and/or a rack;
a mounting ear, wherein the mounting ear is actively connected to the mounting mechanism, and has a working state of being mounted on the mounting mechanism and a disassembled state of being separated from the mounting mechanism and the mounting ear is internally provided with a control board configured to be electrically connected to a device in the chassis; and
a locking mechanism, wherein the locking mechanism is arranged between the mounting ear and the mounting mechanism and is able to lock the mounting ear in the working state, the locking mechanism is provided with an operating end for unlocking, and the operating end is located at a front surface or a side surface of the mounting ear

2. The mounting ear apparatus according to claim 1, wherein the mounting ear is movably connected to the mounting mechanism, and a moving direction of the mounting ear relative to the mounting mechanism is non-parallel to a direction in which the chassis extends out of the rack.

3. The mounting ear apparatus according to claim 1, wherein the mounting ear apparatus further comprises a limiting mechanism, the limiting mechanism comprises a first limiting portion arranged on the mounting ear and a second limiting portion arranged on the mounting mechanism the first limiting portion and the second limiting portion all extend in a moving direction of the mounting ear, and in response to the mounting ear being mounted on the mounting mechanism the first limiting portion abuts against the second limiting portion.

4. The mounting ear apparatus according to claim 3, wherein at least one of the first limiting portion and the second limiting portion is provided with a sliding slot and in response to the first limiting portion and the second limiting portion matching each other in a butted manner, a portion of the first limiting portion is located in the sliding slot of the second limiting portion and/or a portion of the second limiting portion is located in the sliding slot of the first limiting portion.

5. The mounting ear apparatus according to claim 4, wherein the second limiting portion is of an L-shaped structure, an end of the second limiting portion is connected to the mounting mechanism and the sliding slot is enclosed by the L-shaped structure and a surface of the mounting mechanism.

6. The mounting ear apparatus according to claim 3, wherein
there are a plurality of first limiting portions and a plurality of second limiting portions and the plurality of first limiting portions are arranged in one-to-one correspondence to the plurality of second limiting portions, and two opposite sides of the mounting ear are both provided with the first limiting portion; and/or
the first limiting portion and the second limiting portion are provided with a guide rail structure.

7. (canceled)

8. The mounting ear apparatus according to claim 3, wherein the limiting mechanism further comprises a third limiting portion arranged on the mounting ear and a fourth limiting portion arranged on the mounting mechanism, the third limiting portion and the fourth limiting portion extend in a direction perpendicular to the moving direction of the mounting ear and in response to the mounting ear being mounted on the mounting mechanism in place, the third limiting portion abuts against the fourth limiting portion.

9. The mounting ear apparatus according to claim 8, wherein
one of the third limiting portion and the fourth limiting portion is a protrusion, the other one of the third limiting portion and the fourth limiting portion is a recess, an extension direction of the protrusion and an opening direction of the recess both extend in the moving direction of the mounting ear, and in response to the mounting ear being mounted on the mounting mechanism in place, the protrusion is located in the recess; and/or
the third limiting portion and the fourth limiting portion are located at one of two opposite sides of the mounting ear.

10. (canceled)

11. The mounting ear apparatus according to claim 3, wherein the mounting ear comprises a housing, a side of the housing is an opening side, the opening side is mounted on the mounting mechanism in a butted manner, and the limiting mechanism is arranged at an edge of the opening side.

12. The mounting ear apparatus according to claim 11, wherein the edge of the opening side is provided with a notch allowing a cable to extend out.

13. The mounting ear apparatus according to claim 1, wherein the locking mechanism comprises:
a locking member wherein the locking member is actively connected to the mounting ear; and
a locking hole wherein the locking hole is located on the mounting mechanism and in response to the mounting ear being in the working state, the locking member is located in the locking hole and prevents the mounting ear from moving to the disassembled state.

14. The mounting ear apparatus according to claim 13, wherein the locking member is movably arranged relative to the mounting ear, and a moving direction of the locking member is non-parallel to a moving direction of the mounting ear mounted on the mounting mechanism.

15. The mounting ear apparatus according to claim 13, wherein the locking member comprises:
a locking portion wherein the locking portion is located in the mounting ear and the locking portion is provided with a locking end configured to match the locking hole; and
an operating portion wherein the operating portion is located at an outer side of the mounting ear, the operating portion and the locking portion are connected to each other and move synchronously, and the operating portion is provided with the operating end.

16. The mounting ear apparatus according to claim 13, wherein the locking mechanism further comprises a locking reset member, the locking reset member abuts against the locking member and provides a reset force for the locking reset member to move in a direction extending into the locking hole

17. The mounting ear apparatus according to claim 1, wherein the mounting mechanism comprises a mounting portion and a housing portion the mounting portion is connected to the housing portion the locking mechanism is located at the mounting portion and the housing portion is provided with an accommodating cavity configured to accommodate a component.

18. The mounting ear apparatus according to claim 1, wherein the mounting ear apparatus further comprises a stretchable mechanism, the stretchable mechanism is arranged in the chassis, a cable is wound around the stretchable mechanism at least a portion of the stretchable mechanism is actively arranged, in response to the mounting ear being in the disassembled state, the cable connected to the mounting ear drives the stretchable mechanism to move, such that a length of the cable extending out of the chassis is increased, and in response to the mounting ear being in the working state, the stretchable mechanism drives the cable to retract into the chassis.

19. The mounting ear apparatus according to claim 18, wherein the stretchable mechanism comprises:
a support, wherein the support is arranged in the chassis; and
a sliding member, wherein the sliding member is movably arranged on the support, the cable winds through the sliding member, and in response to the mounting ear being disassembled, the mounting ear pulls the cable, and the cable drives the sliding member to move, such that the length of the cable extending out of the chassis is changed.

20. The mounting ear apparatus according to claim 19, wherein
a moving direction of the sliding member is parallel to an extension direction of the cable; and/or
the sliding member is provided with a winding column, and the cable winds through the winding column, and drives the winding column to pull the sliding member to move; and/or
the support has a sliding region, the sliding region extends in a moving direction of the sliding member, and the sliding member is accommodated in the sliding region.

21. (canceled)

22. The mounting ear apparatus according to claim 19, wherein the stretchable mechanism further comprises a stretchable reset member, and the stretchable reset member is connected to the sliding member and drives the sliding member to move in a direction of pulling the cable to retract into the chassis.

23. (canceled)

24. A server, comprising a chassis and the mounting ear apparatus for a server according to claim 1, the mounting ear apparatus is mounted on the chassis.
